(19) United States
(12) Patent Application Publication
(10) Pub. No.: US 2026/0247881 A1
(43) Pub. Date: Aug. 20, 2026

(54) DIELECTRIC ETCH USING CARBON BASED LINER

(71) Applicant: Lam Research Corporation, Fremont, CA (US)

(72) Inventors: Qing XU, Fremont, CA (US); Walter Thomas RALSTON, San Jose, CA (US); Sangchul LEE, Pleasanton, CA (US); Merrett WONG, Palo Alto, CA (US); Ming-Yuan CHUANG, San Jose, CA (US)

(21) Appl. No.: 19/162,615

(22) PCT Filed: Mar. 26, 2024
(86) PCT No.: PCT/US2024/021502

§ 371 Date: Sep. 5, 2025

Related U.S. Application Data
(60) Provisional application No. 63/493,435, filed on Mar. 31, 2023.

(51) Int. Cl. H10P 14/60; C23C 16/02; C23C 16/455; C23C 16/56; H10P 50/00; H10P 50/28

(52) U.S. Cl. CPC H10P 14/6336; C23C 16/0227; C23C 16/45536; C23C 16/45553; C23C 16/56; H10P 50/283; H10P 50/73

(57) ABSTRACT

A method of etching features in a stack with a silicon containing dielectric layer is provided. Features are partially etched in the stack, wherein the features have sidewalls. A carbon containing liner is deposited on the sidewalls of the features, comprising providing a pressure of at least 100 mTorr, providing a deposition gas comprising a carbon containing passivation component, and forming a plasma from the deposition gas, wherein the plasma deposits a carbon containing sidewall deposition on the sidewalls of the features. The features are further etched.

### CROSS-REFERENCE TO RELATED APPLICATION

This application claims the benefit of priority of U.S. Application No. 63/493,435, filed Mar. 31, 2023, which is incorporated herein by reference for all purposes.

### BACKGROUND

One process frequently employed during the fabrication of semiconductor devices is the formation of an etched cylinder or other recessed feature in a silicon containing dielectric material. The silicon containing dielectric material may be alternating/repeating layers into which the recessed feature is formed or a thick film of a single layer of silicon-containing material. One example context where such a process may occur is memory applications such as DRAM (dynamic random access memory) and NAND (not and devices). As the semiconductor industry advances and device dimensions become smaller, such recessed features become increasingly harder to etch in a uniform manner, especially for high aspect ratio features having narrow widths and/or deep depths.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method of etching features in a stack with a silicon containing dielectric layer is provided. Features are partially etched in the stack, wherein the features have sidewalls. A carbon containing liner is deposited on the sidewalls of the features, comprising providing a pressure of at least 100 mTorr, providing a deposition gas comprising a carbon containing passivation component, and forming a plasma from the deposition gas, wherein the plasma deposits a carbon containing sidewall deposition on the sidewalls of the features. The features are further etched.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 depicts a flow chart describing a method of etching recessed features into a stack containing dielectric material according to various embodiments.

FIGS. 2A-2E illustrate a stack that is processed according to certain embodiments.

FIGS. 3A-3B illustrate another stack that is processed according to certain embodiments.

FIG. 4 illustrates a reaction chamber that may be used to perform the techniques described herein according to certain embodiments.

FIG. 5 illustrates a computer system for implementing a controller used in embodiments of the present inventions.

In the drawings, like reference numerals are sometimes used to designate like structural elements. It should also be appreciated that the depictions in the figures are diagrammatic and not to scale.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Fabrication of certain semiconductor devices involves etching features into a stack of materials using plasma-based etch processes. In various embodiments herein, the stack of materials includes alternating/repeating layers of dielectric material. In a number of cases, at least one of the layers in the stack is or includes silicon containing layer. Silicon containing layers may contain silicon nitride, silicon oxide, silicon carbide, silicon oxy-nitride, silicon oxy-carbide, polysilicon, or silicon germanium. In one example, the stack includes alternating layers of silicon oxide and polysilicon. In some embodiments, the stack comprises an alternating silicon oxide film with silicon nitride films or single silicon oxide layer.

The features etched into silicon containing materials may be cylinders, trenches, or other recessed features. The aspect ratio of such a feature is defined as the depth divided by the lateral critical dimension. As the aspect ratio of such features continues to increase, several issues arise including (1) twisting of the features, (2) non-circularity of the features, (3) aspect-ratio dependent etch rate, (4) bowing etch profile, (5) insufficient mask selectivity, and (6) low etch rate.

Twisting refers to random deviations between the intended bottom locations of the features and the actual final bottom locations of the features (e.g., with the final location of a feature corresponding to the position of the bottom of the feature after the feature is etched). For instance, in some cases, it is intended that cylindrical features are etched in a regular array. When some or all features randomly deviate at the bottom away from this array, they are understood to have twisted. Twist may be measured by the degree to which the features deviate away from the desired array pattern. The twist reported herein is the standard deviation of hole-to-hole distance at the bottom of the features, multiplied by three. Because twist is not a desirable feature, it is preferable for it to be as low as possible.

Non-circularity of the features, also described as ellipticity, refers to deviations of the bottom hole shape away from a circular hole shape. This issue is relevant when etching circular features such as cylinders, where it is desired that the bottoms of the recessed features are circular. When the bottom hole shape deviates away from a circular shape, it often forms a shape closer to an ellipse, triangle, or irregular polygon. In many cases, these non-circular shapes are not desirable. Ellipticity may be measured by the degree to which the bottoms of cylindrical features deviate from a perfect circle towards an elliptical shape and is calculated as the ratio of major axis length to minor axis length for an ellipse fitted to the bottom hole shape. Features that are perfect circles have an ellipticity of 1.0. Because circular features are often desired (e.g., when etching cylinders), it is preferable for the ellipticity to be close to 1.0. In various embodiments, mask features that have a circular cross section result in features with an average ellipticity in the range of 1.0 to 1.1.

Aspect-ratio dependent etch rate refers to an issue where the etch rate slows down as the aspect ratio of the features increases. In other words, as the features are etched further into the dielectric material, the etching process slows down. This issue is problematic because it can lead to low throughput and associated high processing costs.

Bowing etch profile refers to the tendency for the features to etch laterally in the dielectric layer such that the final profile bows outwards excessively somewhere along the depth of the features. In other words, the actual maximum critical dimension of the features exceeds the desired maximum critical dimension of the features, which can compromise the integrity of the structures being formed or limit the electrical performance of the final devices.

Insufficient mask selectivity is problematic when the etch process removes an excessive amount of mask, such that no mask remains at the end of the process, or that the amount of mask remaining is insufficient to properly transfer the pattern from the mask to the dielectric film(s). One common result of insufficient mask selectivity is the degradation of the feature profile near the top of the recessed features.

Low etch rate refers to an etch rate that is slower than desired for a particular application. Low etch rate is problematic because it leads to long etch times, reduced throughput, and high processing costs.

Unfortunately, techniques that improve some of these issues often make other issues worse. As such, these issues are balanced against one another when designing an etching operation. For example, conventional commercially practiced dielectric etch processes often result in substantial bowing. Previously, such tradeoffs have been difficult to avoid.

The techniques described herein may be used to etch recessed features into dielectric material without some or all of the issues identified above. In other words, the disclosed techniques may be used to etch recessed features into dielectric material with little or no twisting, reasonably circular features, an acceptable degree of aspect ratio dependent etch rate, acceptable bowing, sufficient mask selectivity, and sufficient etch rate.

In various embodiments herein, an etch process is provided that provides a plurality of cycles of etching a stack with at least one dielectric layer and depositing a carbon containing sidewall passivation. The carbon containing sidewall passivation uniformly deposits on the sidewalls of the features.

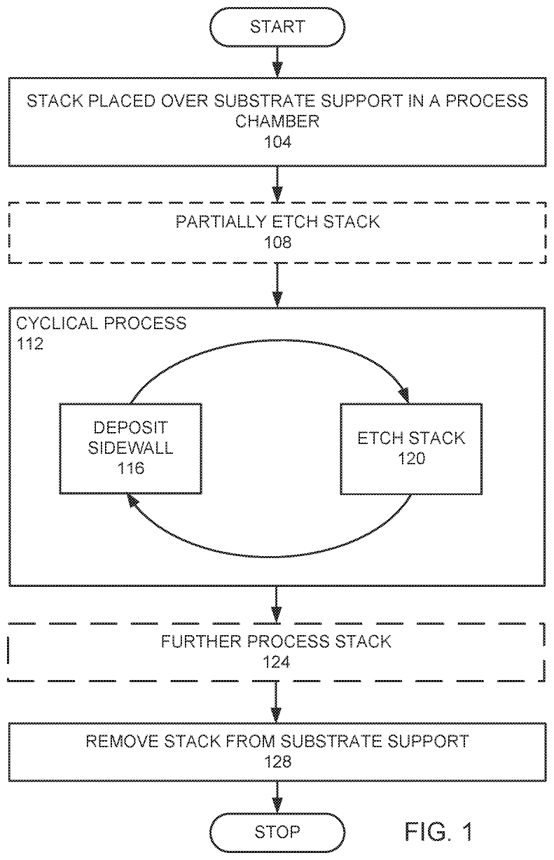

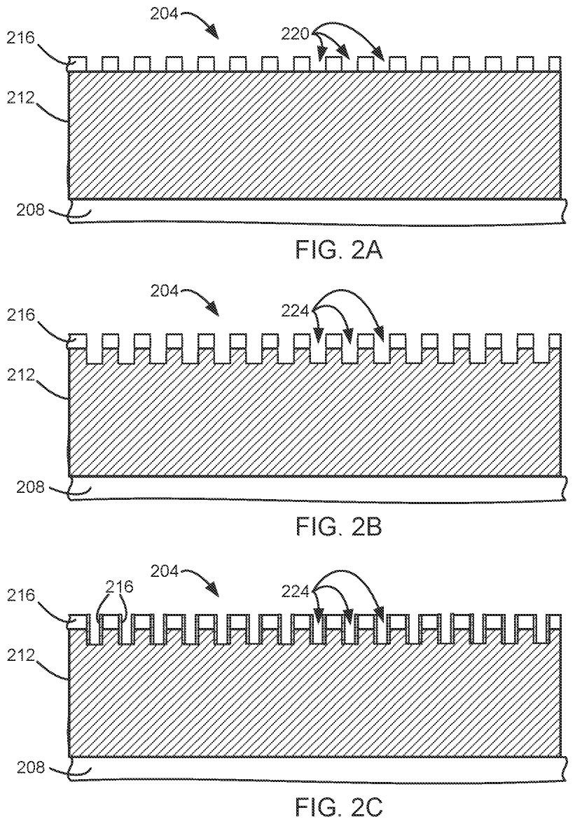

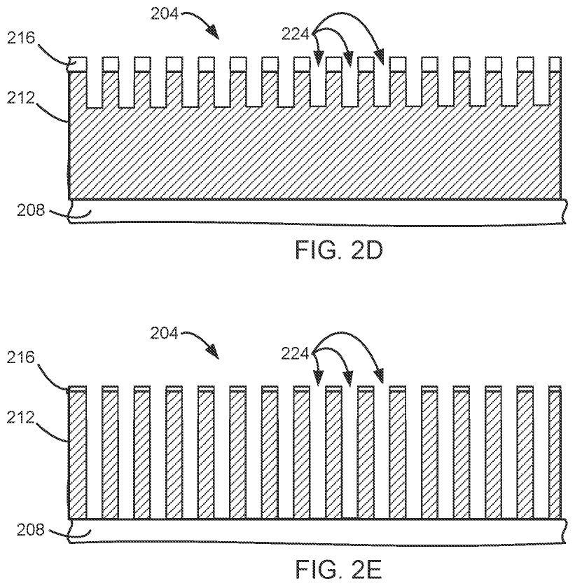

To facilitate understanding, FIG. 1 is a flow chart of a process that may be used in some embodiments. A stack is placed over a substrate support in a process chamber (step 104). FIG. 2A is a schematic cross-sectional view of a stack 204 that may be processed according to some embodiments. The stack 204 may be formed over a substrate 208. Stack 204 is a layer of silicon oxide (SiO₂) 212 under a polysilicon (Si) mask 216 with mask features 220. In some embodiments, one or more layers may be between the layer of silicon oxide 212 and the substrate 208. In some embodiments, one or more layers may be between the layer of silicon oxide 212 and the polysilicon or doped polysilicon mask 216. In some embodiments, the mask features have a CD of less than 25 nanometers (nm). In some embodiments, the mask features have a CD of less than 20 nm. A silicon oxide layer includes silicon oxide based layers. Silicon oxide based layers are silicon oxide layers that may also include one or more dopants. Similarly, a polysilicon layer also includes a polysilicon layer with at least one dopant resulting in a polysilicon based layer. A silicon nitride layer includes a silicon nitride layer with at least one dopant forming a silicon nitride based layer.

In some embodiments, the stack 204 is partially etched (step 108). This partial etch is optional and is not performed in some embodiments. FIG. 2B is a schematic cross-sectional view of the stack 204 after features 224 are partially etched into the stack 204.

Next, a cyclical process is provided (step 112). In some embodiments, the cyclical process (step 112) comprises one or more cycles of depositing a carbon containing sidewall layer (step 116) and etching the stack (step 120). In some embodiments, the depositing of the carbon containing sidewall layer comprises providing a pressure of at least 100 mTorr, providing a deposition gas comprising a carbon containing passivation component. In some embodiments, the deposition gas comprises nitrogen (N₂) and at least one of a hydrocarbon and fluorohydrocarbon. In some embodiments, the deposition gas comprises nitrogen (N₂) at least one of a hydrocarbon and a hydrofluorocarbon, and at least one of a metal halide and carbonyl sulfide. In some embodiments, the metal halide comprises at least one of molybdenum hexafluoride and tungsten hexafluoride. The most significant improvements were obtained when the deposition gas comprised nitrogen (N₂), tungsten hexafluoride, and at least one of a hydrocarbon or hydrofluorocarbon. A plasma is formed from the deposition gas, where the plasma deposits a carbon containing sidewall deposition on the sidewalls of the features. FIG. 2C is a schematic cross-sectional view of the stack 204 after the carbon containing sidewall layer 228 has been deposited on the sidewalls of the features 224. The carbon containing sidewall layer 228 is not drawn to scale but is shown as being thicker in order to more clearly see the carbon containing sidewall layer 228.

After the carbon containing sidewall layer has been deposited (step 116) the stack is etched (step 120). In some embodiments, a reactive ion etch is used. In some embodiments, a chemical etch is used. In some embodiments, a combination of a reactive ion etch and a chemical etch is used. In some embodiments, the etch (step 120) is provided using a chamber pressure of less than 50 mTorr. In some embodiments, the etch (step 120) is provided using a chamber pressure of less than 10 mTorr. FIG. 2D is a schematic cross-sectional view of the stack 204 after the etch. The features 224 are etched deeper. The carbon containing sidewall layer 228, shown in FIG. 2C, has been etched away. In some embodiments, the carbon containing sidewall layer 228 is etched but not etched away.

In some embodiments, the depositing of the carbon containing sidewall layer (step 116) and the etching of the stack (step 120) are cyclically repeated for a plurality of cycles until the etching of the features is completed. During each cycle, the pressure in the chamber goes from above 100 mTorr to less than 50 mTorr. FIG. 2E is a schematic cross-sectional view of the stack 204 after the etch of the features 224 is completed. The mask 216 is etched. In some embodiments, the mask 216 is completely etched away. The stack may be optionally further processed in the process chamber (step 124). In some embodiments, if the mask 216 is not completely etched away, the optional process may remove the remaining mask 216 and any remaining passivation layer. The stack is removed from the substrate support in the process chamber (step 128). Since in this example, the stack remains on the substrate support during the partial etch (step 108) and the cyclical process (step 112), the partial etch (step 108) and the cyclical process (step 112) are performed in-situ in the same process chamber.

It has been found that depositing a carbon containing sidewall layer using a deposition gas comprising nitrogen (N₂), a tungsten hexafluoride, and at least one of a hydrocarbon or hydrofluorocarbon at a pressure above 100 mTorr provides a carbon containing sidewall layer that uniformly deposits on silicon oxide with respect to other materials such as polysilicon. It was found by experiment that N₂ was critical. Experiments found that methane (CH₄), fluoromethane (CH₃F), or difluoromethane (CH₂F₂) provide uniform carbon deposition. In addition, it was found that a high pressure above 100 mTorr was needed. In some embodiments, the pressure was in the range of 100 mTorr to 600 mTorr. In some embodiments, the pressure was in the range of 200 mTorr to 500 mTorr. In some embodiments, the sidewall deposition layer is a carbon containing layer that is metal free.

In some embodiments, the carbon containing component is difluoroethylene (C₂H₂F₂). It has been found by experiment that difluoroethylene provides improved sidewall protection. In some embodiments, the deposition gas comprises an additive of at least one of hydrogen bromide (HBr) and silicon tetrachloride (SiCl₄). They can cause carbon deposition to be more conformally deposited further down the feature improving sidewall protection further down the features.

Prior art carbon deposition processes deposit more carbon on polysilicon than silicon oxide. As a result, for a stack, as shown in FIG. 2A, the increased carbon deposition on the sides of the polysilicon could cause bread loafing which would close features with a CD of less than 20 nm or may cause an etch stop of such features. By providing a carbon deposition that is uniform, the feature with a CD of less than 20 nm is not closed. In addition, the carbon deposition protects the sidewall of the features in order to reduce bowing. The bowing creates a maximum CD at the location of the bowing. Other methods may be used to reduce bowing. However, the other methods may increase etch time, reduce etch selectivity, increase twisting, increase non-circularity, increase aspect ratio dependent etching, increase etch stop, increase feature plugging, or may cause other detrimental etch effects. By providing a uniform sidewall passivation, an additional control tool is added to allow a reduction of bowing and a reduction in CD without increasing other detrimental etch effects. In some experiments, it was found that for features with a CD of about 20 nm.

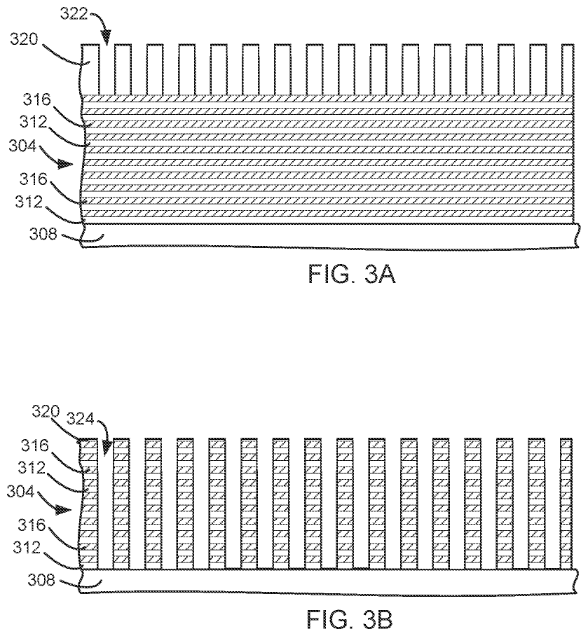

In some embodiments, FIG. 3A is a schematic cross-sectional view of another stack 304 that may be processed according to some embodiments. In some embodiments, the stack 304 may be formed over a substrate 308. One or more layers may be disposed between the stack 304 and the substrate 308. In some embodiments, the stack 304 is a plurality of at least bilayers of a layer of silicon oxide (SiO₂) 316 and a layer of polysilicon (Si) 312 or silicon nitride (SiN). A mask 320 with mask features 322 may be formed over the stack 304. In some embodiments, the mask 320 is a carbon-containing mask, such as an organic mask, one example of which would be an amorphous carbon mask. An amorphous carbon mask may also include some amount of hydrogen and/or oxygen.

The stack 304 is placed over a substrate support in a process chamber (step 104). The cyclical process is provided (step 112). In some embodiments, the depositing of the carbon containing sidewall layer (step 116) and the etching of the stack (step 120) are cyclically repeated for a plurality of cycles until the etching of the features is completed. A recipe for etching the stack (step 120) is a recipe that uniformly etches the layers of silicon oxide 316 and the layers of polysilicon 312 or silicon nitride. The depositing of the carbon containing sidewall layer (step 116) comprising providing a pressure of at least 100 mTorr, providing a deposition gas comprising nitrogen (N₂), tungsten hexafluoride, and at least one of a hydrocarbon or hydrofluorocarbon, and forming a plasma from the deposition gas has been found to uniformly deposit carbon containing sidewall deposition on the sidewalls of the layers of silicon oxide 316 and the layers of polysilicon 312 or silicon nitride. FIG. 3B is a schematic cross-sectional view of the stack 304 after features 324 have been etched. The sides of the features are uniform between the layers of silicon oxide 316 and the layers of polysilicon 312 or silicon nitride. The prior art would deposit more carbon on the sidewalls of layers of polysilicon 312 or silicon nitride than on the sidewalls of layers of silicon oxide 316 causing the sidewalls of the layers of silicon oxide 316 to be etched more making the sides of the features nonuniform, such as a scalloped sidewall.

One application for the disclosed methods is in the context of forming a vertical NAND device. In this case, the material into which the feature is etched may have a repeating layered structure. For instance, the material may include alternating layers of silicon oxide and polysilicon or alternating layers of silicon oxide and silicon nitride. The alternating layers form pairs or repeating groups of materials. In various cases, the number of pairs or repeating groups may be between about 10-500 (e.g., between about 20-1000 individual layers). The feature etched into the stack of layers may have a depth between about 2-15 μm, for example between about 5-9 μm. The feature may have a width between about 10-100 nm, for example between about 10-50 nm. In some embodiments, the features have a width of less than 20 nm. In some embodiments, the features have a width of less than 15 nm.

As used herein, “high aspect ratio” as applied to features in a substrate refers to depth to width aspect ratios on the order of approximately 60:1 or higher. More preferably, this range may include ratios greater than 100:1, 120:1, 140:1, etc., or higher. However, the processes described herein may be beneficial for lower aspect ratios, such as 30:1, or 10:1.

There are many types of mask layers that may be used with the described embodiments, which will include any such layer known in the art which may serve as an etching mask. For example, the mask may be a carbon hard mask, such as amorphous carbon. In other embodiments, the mask may be a doped carbon. In some embodiments, the mask may contain silicon, a metal, or a metalloid.

The dimensional/parametric details provided herein, such as height, aspect ratio, thickness, width, depth, etc., are for example and illustration only. Based on the disclosure described herein, it should be understood that varying dimensions/parameters may also be applicable or used.

### Apparatus

The various hardware and method embodiments described above may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon containing film formed thereon, using a spin-on or spray-on tool; (2) curing of photoresist using a hot plate or furnace or other suitable curing tool; (3) exposing the photoresist to visible or ultraviolet (UV) or x-ray light with a tool such as a wafer stepper; (4) developing the resist so as to selectively remove the resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, 300 mm, or 450 mm. The above detailed description assumes the embodiments are implemented on a wafer. However, the embodiments are not so limited. The workpiece may be of various shapes, sizes, and materials. In addition to semiconductor wafers, other work pieces that may take advantage of the disclosed embodiments include various articles such as printed circuit boards, magnetic recording media, magnetic recording sensors, mirrors, optical elements, micro-mechanical devices, and the like.

Unless otherwise defined for a particular parameter, the terms “about” and “approximately” as used herein are intended to mean ±10% with respect to a relevant value.

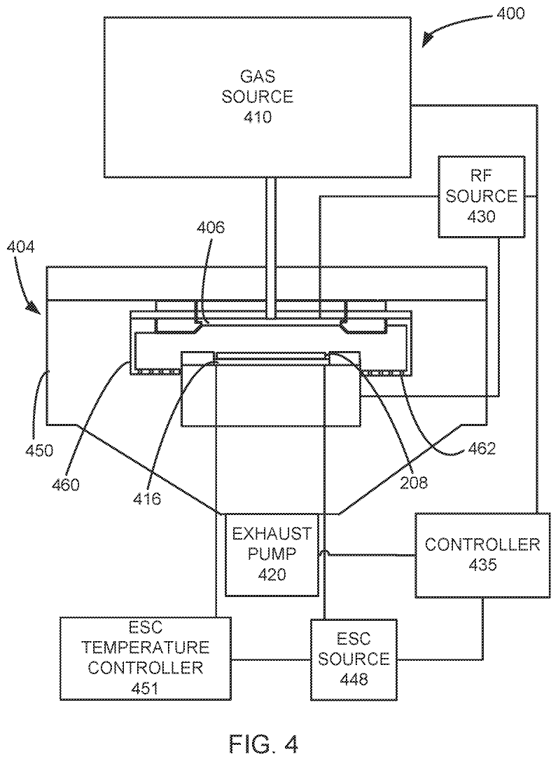

FIG. 4 is a schematic view of a plasma processing chamber 400 for plasma processing substrates, in an embodiment. In one or more embodiments, the plasma processing chamber 400 comprises a gas distribution plate 406 providing a gas inlet and an electrostatic chuck (ESC) 416, within a plasma processing chamber 404, enclosed by a chamber wall 450. Within the plasma processing chamber 404, the substrate 208 is positioned on top of the ESC 416 so that the ESC 416 is a substrate support. The ESC 416 may provide a bias from an ESC power source 448. A gas source 410 is connected to the plasma processing chamber 404 through the gas distribution plate 406. An ESC temperature controller 451 is connected to the ESC 416 and provides temperature control for the ESC 416. A radio frequency (RF) power source 430 provides RF power to the ESC 416 and an upper electrode. In this embodiment, the upper electrode is the gas distribution plate 406. In a preferred embodiment, 400 kilohertz (kHz), 13.56 megahertz (MHz), 1 MHz, 2 MHz, 60 MHz, and/or optionally, 27 MHz power sources make up the RF power source 430 and the ESC power source 448. A controller 435 is controllably connected to the RF power source 430, the ESC power source 448, an exhaust pump 420, and the gas source 410. A high flow liner 460 is a liner within the plasma processing chamber 404, which confines gas from the gas source and has slots 462. The slots 462 maintain a controlled flow of gas to pass from the gas source 410 to the exhaust pump 420. An example of such a plasma processing chamber is the Flex® etch system manufactured by Lam Research Corporation of Fremont, CA. The process chamber can be a CCP (capacitively coupled plasma) reactor or an ICP (inductively coupled plasma) reactor.

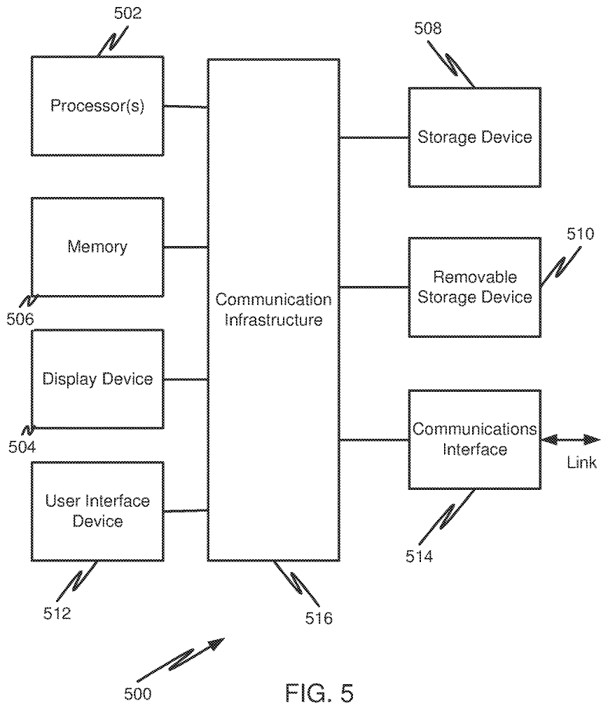

FIG. 5 is a high level block diagram illustrating a computer system 500 for implementing the controller 435 used in embodiments of the present inventions. The computer system may have many physical forms ranging from an integrated circuit, a printed circuit board, and a small handheld device up to a huge supercomputer. The computer system 500 may include one or more processors 502 and further can include an electronic display device 504 (for displaying graphics, text, and other data), a main memory 506 (e.g., random access memory (RAM)), storage device 508 (e.g., hard disk drive), removable storage device 510 (e.g., optical disk drive), user interface devices 512 (e.g., keyboards, touch screens, keypads, mice or other pointing devices, etc.), and/or a communication interface 514 (e.g., wireless network interface). The communication interface 514 may allow software and/or data to be transferred between the computer system 500 and external devices via a link. The system may also include a communications infrastructure 516 (e.g., a communications bus, cross-over bar, or network) to which the aforementioned devices/modules may be connected.

Information transferred via communications interface 514 may be in the form of signals such as electronic, electromagnetic, optical, or other signals capable of being received by communications interface 514, via a communication link that carries signals and may be implemented using wire or cable, fiber optics, a phone line, a cellular phone link, a radio frequency link, and/or other communication channels. With such a communications interface, it is contemplated that the one or more processors 502 might receive information from a network or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as that produced by a compiler, and files containing higher level code that are executed by a computer using an interpreter. Computer readable media may also be computer code transmitted by a computer data signal embodied in a carrier wave and representing a sequence of instructions that are executable by a processor.

It is to be understood that the configurations and/or approaches described herein are exemplary in nature and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed. The subject matter of the present disclosure includes all novel and nonobvious combinations and sub-combinations of the various processes, systems, and configurations, and other features, functions, acts, and/or properties disclosed herein, as well as any and all equivalents thereof.

### CONCLUSION

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method of etching features in a stack with a silicon containing dielectric layer, the method comprising:
a. partially etching features in the stack, wherein the features have sidewalls;
b. depositing a carbon containing liner on the sidewalls of the features, comprising:
providing a pressure of at least 100 mTorr;
providing a deposition gas comprising a carbon containing passivation component; and
forming a plasma from the deposition gas, wherein the plasma deposits a carbon containing sidewall deposition on the sidewalls of the features; and
c. further etching the features.

2. The method, as recited in claim 1, wherein a pressure of at least 100 mTorr is a pressure in a range of 100 mTorr to 600 mTorr.

3. The method, as recited in claim 1, wherein the pressure of at least 100 mTorr is a pressure in a range of 200 mTorr to 500 mTorr.

4. The method, as recited in claim 1, wherein the deposition gas comprises, nitrogen (N₂), and at least one of a hydrocarbon and a hydrofluorocarbon.

5. The method, as recited in claim 4, wherein the deposition gas further comprises at least one of a metal halide and carbonyl sulfide.

6. The method, as recited in claim 4, wherein the deposition gas further comprises tungsten hexafluoride.

7. The method, as recited in claim 4, wherein the at least one of a hydrocarbon and a hydrofluorocarbon comprises at least one of fluoromethane (CH₃F), difluoromethane (CH₂F₂), and methane (CH₄).

8. The method, as recited in claim 4, wherein the at least one of a hydrocarbon and a hydrofluorocarbon comprises methane (CH₄).

9. The method, as recited in claim 1, wherein steps b and c are repeated for at least two cycles.

10. The method, as recited in claim 1, wherein steps a through c are performed in-situ, within a processing chamber.

11. The method, as recited in claim 10, wherein a pressure of no more than 50 mTorr is provided during the further etching of the features.

12. The method, as recited in claim 1, wherein the silicon containing stack comprises at least one silicon oxide based layer, wherein either the partially etching features or further etching the features etches the at least one silicon oxide based layer.

13. The method, as recited in claim 1, wherein at least some of the features have a CD of less than 25 nm.

14. The method, as recited in claim 1, wherein the further etching of the features is a reactive ion etch.

15. The method, as recited in claim 1, wherein the stack comprises at least one silicon oxide containing layer below a polysilicon or doped polysilicon mask and wherein the further etching of the features selectively etches the at least one silicon oxide containing layer with respect to the polysilicon or doped polysilicon mask.

16. The method, as recited in claim 1, wherein the stack comprises a plurality of at least bilayers, wherein each at least bilayer comprises at least one silicon oxide layer and at least one of a silicon nitride and polysilicon layer, and wherein the further etching the features uniformly etches the at least one silicon oxide layer and the at least one of a silicon nitride and polysilicon layer.

17. The method, as recited in claim 1, wherein the carbon containing passivation component comprises difluoroethylene (C₂H₂F₂).

18. The method, as recited in claim 1, wherein the deposition gas comprises at least one of hydrogen bromide (HBr) and silicon tetrachloride (SiCl₄) and at least one of a hydrocarbon and a hydrofluorocarbon.
